(19) United States
(12) Patent Application Publication
(10) Pub. No.: US 2012/0045627 A1
(43) Pub. Date: Feb. 23, 2012

(54) COATINGS WITH SMALL PARTICLES THAT EFFECT BULK PROPERTIES

(76) Inventors: Jainagesh Sekhar, Cincinnati, OH (US); Ganta Reddy, Cincinnati, OH (US)

(21) Appl. No.: 13/318,366

(22) PCT Filed: May 22, 2009
(86) PCT No.: PCT/US09/45068

§ 371 Date: Nov. 1, 2011

(51) Int. Cl. B32B 3/00; C23C 16/50

(52) U.S. Cl. 428/195.1; 118/620

(57) ABSTRACT

Durable interactive coatings which may be deposited on a substrate which impact bulk properties i.e. bulk modifying coatings, and a method and apparatus for producing them. Such coatings can include a plurality of particles which adhere to the substrate surface and/or other particles and include films. The particles can be provided as one or more layers of nanoscale particles having an average size of less than about 1000 nm, 800 nm, 500 nm, or 200 nm or 100 nm or less than 50 nm. Such bulk modifying coatings can have a thickness that is less than about 5000 nm, 800 nm, 500 nm, or 250 nm or even 200 nm. Thicker coatings or thinner coatings are provided depending on the potential field thermodynamic interaction of the substrate and particles for bulk property enhancement. Corresponding films are also provided.

### FIELD OF THE INVENTION

The present invention relates to materials having durably adherent particulate which influence the bulk properties of a material.

### BACKGROUND

Surface coatings are normally used to improve surface related properties of a material such as oxidation, corrosion or surface wear. Should bulk properties be influenced by coatings, then the possibility of enhancing several known alloys, including metal, ceramics and polymers or even repairing alloys during field operations may become possible leading to industrial and commercial applications in a variety of fields ranging from biomedical implants to boilers in ultra supercritical and supercritical energy generation (herein referred to as USC) to electro ceramics to transportation vehicles.

In certain industries like power generation there is a strong energy and environmental impact with advanced materials which can withstand higher temperatures or last longer in service. In the energy industry each percentage increase in energy efficiency gives rise to about an effective 2% reduction in CO₂ and SO₂ emissions. The goal of improving the efficiency of pulverized coal power plants has been pursued for decades. The need for greater fuel efficiency and reduced environmental impact is pushing utilities to USC conditions, i.e. steam conditions of 760° C. and 35 MPa. The long-term fatigue, creep-strength, erosion and environmental resistance requirements imposed by these conditions are rather severe and clearly beyond the capacity of many currently used materials and coatings. It is expected that maximum waterfall temperatures in high efficiency units will approach 600-625° C., with super-/re-heater outlet temperatures expected to approach ≧750° C. with high heat flux. Material degradation through steam oxidation, sulfidation, carburization, molten salt and other corrosion mechanisms at these higher operating temperatures may severely limit the serviceable lives of critical components and is the primary impediment toward meeting the desired fuel efficiency and environmental standards of these next-generation power generation systems that include coal-fired boilers, gas turbines, and solid oxide fuel cells (SOFCs).

Certain industries, such as the health care and medical industry, may have a particular need for strong materials because then the design can be lighter and section thicknesses smaller e.g. in medical needles to food processing applications. In the transportation industry, including land, sea, air, and space vehicles, there may also be particular materials which need advanced material properties with a further requirement for insitu repair of such materials . . . . Protection from oxidation is necessary for a wide variety of applications, from gas turbine engines, steam turbines, chemical processing, petroleum refining, to metal foil catalytic converters for automobiles. As the LHV (lower heating value) is improved (from 40% to more than 50%), a one percent increase in efficiency reduces by two percent, specific emissions such as CO₂, NOx, SOx and particulate matters. Improvements are possible with an increase in the temperature and pressure of boilers. Such boilers can be used in coal plants to nuclear installations. Supercritical and ultra supercritical power plants are highly efficient plants with best available pollution control technology. Such boilers are ‘green’ because they reduce existing pollution levels by burning less coal per megawatt-hour produced. There is a significant thrust in this direction—several installations are now using USC boilers. Power plants are coming-up with this state-of-the-art technology. As environment legislations are becoming more stringent, adopting this cleaner technology could benefit immensely in all respect. Protection against erosion is particularly important for boiler materials such as T11. It is not just enough to have a better surface but also to have better bulk properties which can enhance the overall erosion and fatigue.

PCT/US2006/060621 and PCT/US2007/085564 discuss such coatings, the disclosure of which is incorporated by reference herein. The coatings and surfaces discussed in these two PCT's were thought to influence surface properties, such as emissivity, surface wear, antimicrobial, reflectivity, etc and thus enhance durability but were not necessarily expected to influence bulk properties of the substrate. In particular it has never been anticipated that that a nanocoating will provide significant improvement to bulk properties such as fatigue resistance, bulk creep or erosion over time or wear resistance over time which require bulk material properties to be considered or improved. However surface fatigue crack initiation which is a surface phenomenon can have been thought to be influenced by coatings. In this specification we discuss coatings that influence much more than a surface property namely bulk properties. A surface is a two dimensional object whereas a bulk region has a third dimension (three dimensional object) generally with a thickness at least greater than the coating thickness. The interface between a coating and a surface could be diffuse or sharp i.e. localized to a few atomic layers or just one atomic layer. The word nano is commonly used to signify 10⁻⁹ (most often used with meter as the length unit).

The particle materials and coatings as described herein can be durable because the morphology of the deposited particles (e.g., their approximate size, degree of porosity or interconnectedness, etc.) may be essentially retained during exposure to high temperatures, mechanical forces, chemicals, cyclic conditions of fields etc. A high specific surface area may persist in such particulate coatings and materials, even if some amount of oxide or other reactive compound may form thereon, because of the presence of the initial microscopic or nanoscale particles or from frozen in dissipative waves created during the application process or Landau waves, which can all influence the growth rate of such compounds at least in the initial stages of growth. There are a particular class of applications which invoke properties like fatigue, low crack propagation rate, charge retention (e.g. capacitors), semiconductors, superconductors, resistors, electro ceramics, pizieoceramics, bioimplants (e.g. for bones, spine, valves, hip etc.), electrodes for electrolysis including large electrolysis like aluminum electrowinning, and smaller size electrodes used batteries, multibarrier electronics (e.g. NPN, N and P junctions), where, in particular the bulk material is required to be influenced and controlled. In general, if a thermodynamic potential is induced or modified by the particulate coating, then depending on the strength and distance of the potential field, the bulk properties are influenced. The particulates structure of the coating jointly with the bulk including the modified substrate can thus interact and produce bulk properties which are different from the uncoated state. Sometimes the differences may be significant and sometimes smaller based on the nature of interaction. Thermodynamic potentials can be pressure (stress), electrical, thermal, magnetic, electromotive, mass based, interface energies (like grain boundary energy), chemical potential, energy gradient potential, free energy or even polarons (several types), photonic or phonon fields, dissipative patterns such as chemical oscillations and all the possible interactions between fields including non periodic oscillations.

Metal deformation on a surface by forging, welding, shot peening or laser shot peening are known to modify some bulk properties (non chemical) but these processes do not include particle coating on the substrate. Coatings provide valuable protection for surfaces as has for example been noted in PCT/US2006/060621 and PCT/US2007/085564. In particular the use of nanocoatings has not been anticipated to modify bulk structure properties. Sometimes it is difficult to directly measure a property. A noticeable change of microstructure is an indication of the property change. Articles in transportation (e.g. jet engines parts, automobile parts, steam turbines, nuclear use, space or underwater use etc.), biological implants, household (e.g. knobs, utensils, keys necklaces, switches, buttons etc.), in the energy sector are possible with this invention. Other components for example in energy production or storage such as chimneys, scrubbers, electrostatic precipitators, cleaning systems, igniters, ignition chambers, fluid (gas and liquid) delivery systems, water pipes, clean water systems and tubes, hydraulic systems requiring corrosion resistance and systems used in sequestering SO2, CO2 or other gasses may benefit from this invention. The build of gunk (residue e.g salts) in water tubes may be reduced because of the bulk potential along with surface potential interactions that this invention enables.

For some of the reasons outlined above a durable coating which also impacts bulk properties is desirable. The film could be a consequence of the particles, by itself or a feature that is created by the bulk modifying particles, or from the modified bulk or substrate. The particles could be attached to any of the other features or penetrate the surface as also discussed in the examples. Further, there may be a need to provide such materials and coatings which are easy and relatively inexpensive to produce, and which may be applied to a broad variety of substrates. Further there may be a need for such coatings to be nanosized or comprise of nanoparticles. In addition, there may be a need for such coatings which can be applied to objects that are already in use or that are in need of repair, for example boilers and heat exchangers or tubes which may see hot erosion or corrosion over a long period of usage. Boiler and heat exchanger is a term used interchangeably in this application.

### SUMMARY OF EXEMPLARY EMBODIMENTS OF THE INVENTION

The exemplary embodiments of methods and materials according to the present invention can provide one or more durable coating layers of closely spaced, but partially separated (e.g., not fully sintered) small particles on a substrate which also influence bulk properties. For example, such particles may have an average size that may be less than about 1000 nm, less than about 800 nm, or preferably less than about 500 nm, or preferably less than about 200 nm or more preferably less than 100 nm. The particles may have a shape that is approximately, spherical, cylindrical, acicular, tubular or a mixture of these geometries. Such coatings can have a thickness that is less than about 5000 nm, or preferably less than about 800 nm, or less than about 500 nm. Thicker coatings may also be provided. For example, a coating of small particles may be provided on a substrate using a single-sided electrode arrangement, which can include a power generator, a Pi circuit or equivalent circuit, and an electrode. The power generator can be a high-frequency generator. The electrode materials as well as the particles may be those described for example in PCT/US2006/060621 and PCT/US2007/085564. The use of metals, semiconductors, phosphides, aluminides, nitrides, borides, sulfides, oxides, metalloids and the various organic materials used for engineering and general surface properties use are considered wherever they may be bulk modifying. Ceramic materials are also fully considered including PZT and electro ceramic materials. Defect structures with non equilibrium and non-stoichiometric chemistries are anticipated also, These and other objects, features and advantages of the present invention will become apparent upon reading the following detailed description of embodiments of the invention, when taken in conjunction with the appended claims.

### BRIEF DESCRIPTION OF THE DRAWINGS

Further objects, features and advantages of the invention will become apparent from the following detailed description taken in conjunction with the accompanying figures showing illustrative embodiments of the invention, in which:

FIG. 1 is an illustration of an exemplary apparatus which may be used to produce materials in accordance with certain exemplary embodiments of the present invention;

FIG. 2 is an illustration of the exemplary apparatus which may be used to produce coatings on large substrates in accordance with other exemplary embodiments of the present invention;

FIG. 3 is an illustration of the exemplary apparatus which may be used to produce coatings in accordance with further exemplary embodiments of the present invention;

FIG. 4 is an illustration of the exemplary apparatus which may be used to produce coatings in accordance with additional exemplary embodiments of the present invention;

FIG. 5 is an exemplary image of an exemplary coating provided by a scanning electron microscope (“SEM”) in accordance with certain exemplary embodiments of the present invention on a common household plastic.

FIG. 6 is another exemplary image SEM image of a further exemplary coating in accordance with further exemplary embodiments of the present invention;

FIG. 7 is an exemplary image of an exemplary coating provided by a scanning electron microscope (“SEM”) in accordance with certain exemplary embodiments of the present invention;

FIG. 8 is another exemplary SEM image of a further exemplary coating in accordance with further exemplary embodiments of the present invention;

FIG. 9 is another exemplary SEM image of a further exemplary coating in accordance with further exemplary embodiments of the present invention;

FIG. 10 is another exemplary SEM image of a further exemplary coating in accordance with further exemplary embodiments of the present invention;

FIG. 11 is an another exemplary SEM image of a further exemplary coating in accordance with further exemplary embodiments of the present invention;

FIG. 12: Oxidation plot (weight gain vs. time) of CCA617 in steam at 750° C. for 100 hours with and without embodiments of the invention. The resolution and possible experimental errors are in the order of 0.1 mg/cm². The difference noted because of the invention is substantially higher than any identified resolution or experimental errors;

FIG. 13: Oxidation of (weight gain vs. time), with and without embodiments of this invention, for S304H steel in steam at 700° C. for 100 hours. The resolution and possible experimental errors are in the order of 0.1 mg/cm². The difference noted because of the invention is substantially higher than any identified resolution or experimental error;

FIG. 14: Oxidation of T92 steel in steam at 650° C. for 100 hours;

FIG. 15a. Coated CCA617 oxidized in steam at 750 C for 100 hours. SE (secondary electron image), of surface (top) and BSE (backscattered image) of cross-section (bottom) micrographs. Smaller thickness of the oxide layer (in this case a part of the film) is noted compared with the uncoated. XRD analysis of the oxidized surface showed the presence of Cr₂O₃ containing Si and the FCC matrix;

FIG. 15b. Uncoated CCA617 oxidized in steam at 750 C for 100 hours. SE of surface (top) and BSE of cross-section (bottom) micrographs. Larger thickness of the oxide layer (film) is noted compared to the coated sample. XRD analysis of the oxidized surface showed the presence of Cr₂O₃ and the FCC matrix;

FIG. 16a. Sample S11-5T: Coated Super304H steel oxidized in steam at 700 C for 100 hours. SE of surface (top) and BSE of cross-section (bottom) micrographs. Smaller thickness of the film is noted compared with the uncoated. XRD analysis of the oxidized surface showed the presence of Cr₂O₃ containing Si, (Fe, Cr, Mn)O₄ and the FCC matrix;

FIG. 16b. Sample C4: Uncoated Super304H steel oxidized in steam at 700 C for 100 hours. SE of surface (top) and BSE of cross-section (bottom) micrographs. Larger thickness of the film is noted compared to the coated sample. XRD analysis of the oxidized surface showed the presence of Cr₂O₃, (Fe, Cr, Mn)O₄ and the FCC matrix;

FIG. 17a. Sample T1-5T: Coated T92 steel oxidized in steam at 650 C for 100 hours. SE of surface (top) and BSE of cross-section (bottom) micrographs. Finer oxide particles and much smaller thickness of the film are noted compared with the uncoated 17b. XRD analysis of the oxidized surface showed the presence of Cr₂O₃ containing Si, Fe₂O₃ and the BCC matrix but with a different microstructure that 17(b);

FIG. 17b. Sample T2: Uncoated T92 steel oxidized in steam at 650 C for 100 hours.

SE of surface (top) and BSE of cross-section (bottom) micrographs. Coarser oxide particles and much larger thickness of the film are noted compared to the coated sample. XRD analysis of the oxidized surface showed the presence of Cr₂O₃ containing Si, Fe₂O₃ and the BCC matrix but with a different microstructure than 17(a);

FIG. 18: Comparative Static Air Oxidation of the CCA617 alloy, S304H steel, and T92 steel tube coupons with and without the embodiments of the invention for 500 hours at 700 C, 700 C and 650 C respectively;

FIG. 19: Static Air Oxidation of the CCA617 alloy, S304H steel, and T92 steel tube coupons for 500 hours at 700 C, 700 C and 650 C respectively illustrating benefits of the invention for educed greenhouse emissions and energy usage;

FIG. 20a. Sample C7-5T: Coated CCA617 oxidized in air at 700 C for 500 hours. SE of surface (top) and BSE of cross-section (bottom) micrographs. Oxide and film layer thinner compared with the uncoated sample;

FIG. 20b. Sample C8: Uncoated CCA617 oxidized in air at 700 C for 500 hours. SE of surface (top) and BSE cross-section (bottom) micrographs. Oxide and film layer thicker compared with the coated sample;

FIG. 21a. Sample C9-5T: Coated CCA617 oxidized in air at 700 C for 1000 hours showcasing an embodiment of the invention when compared to 21b;

FIG. 21b. Sample C10: Uncoated CCA617 oxidized in air at 700 C for 1000 hours. BSE micrograph of sample cross-section. Oxide layer thicker compared with the coated sample;

FIG. 22a. Sample T5-5T: Coated T92 steel oxidized in air at 650 C for 1000 hours. BSE micrographs of sample cross-section. Oxide layer thinner compared with the uncoated and number of grain boundary or grain interior bright reflections is very different when compared to 22b;

FIG. 22b. Sample T6: Uncoated T92 steel oxidized in air at 650 C for 1000 hours. BSE micrograph of sample cross-section;

Throughout the drawings, the same reference numerals and characters, unless otherwise stated, are used to denote like features, elements, components, or portions of the illustrated embodiments. Moreover, while the present invention will now be described in detail with reference to the figures, it is done so in connection with the illustrative embodiments and is not limited by the particular embodiments illustrated in the figures.

### DETAILED DESCRIPTION OF EXEMPLARY EMBODIMENTS OF THE INVENTION

Exemplary embodiments of the present invention on a variety of substrates are discussed below. Such coatings can include, e.g., microscopic and/or nanoscale particles of certain materials which may be strongly bonded to a substrate and/or to each other and provide for bulk changes. The coatings may be porous or otherwise not fully sintered or densified.

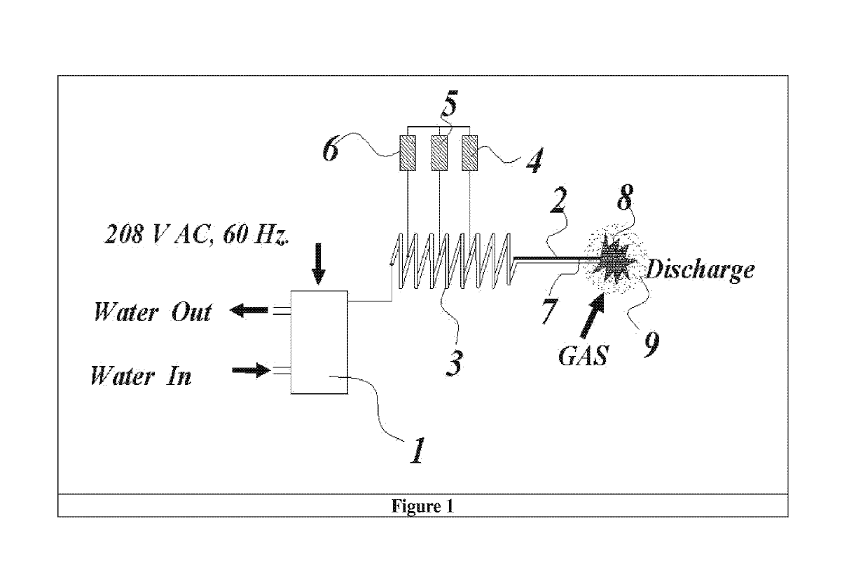

Such coatings may be created by very-strong electrochemical decomposition processes (which unfortunately could passivate most of the time) or such coatings may be applied using exemplary techniques described, e.g., in U.S. patent application Ser. No. 11/098,474 and International Patent Application No. PCT/US06/60621 and PCT/US2007/085564, the entire disclosures of which are incorporated herein by reference in their entireties. These will be referred to as enhanced coating techniques or methods for application of bulk modifying coating. Such exemplary techniques which may be used to provide coatings of small particles are described in more detail herein, and can be used to provide coatings or materials which surprisingly exhibit changes in bulk properties. An exemplary apparatus 100 which can be used to produce bulk modifying coatings and surfaces in accordance with exemplary embodiments of the present invention is shown in FIG. 1. Such exemplary apparatus 100 can be configured to produce an electrical arc or discharge 8 at a distal end of an electrode 2, where the arc or discharge 8 can be produced without the distal end of the electrode 2 being in proximity to an electrically grounded object.

For example, the exemplary apparatus 100 can be based on a one-sided electrode arrangement which may be configured to deposit particles on a substrate or other surface. Such exemplary apparatus 100 can include, e.g., a high-frequency electrical generator or power source 1, a conductive coil 3 which may be provided as a coiled tube, and can be formed, e.g., using copper or another conductive material, and an electrode 2 which can be formed of or include a material to be deposited as at least part of an coating. The electrode 2 may be conductive or semi conductive. Capacitors 4, 5, 6 can be provided in an electrical communication with the conductive coil 3, which may exhibit electrically inductive properties. For example, capacitors 4, 5, 6 and coil 3 may together form a conventional Pi circuit, or exhibit electrical behavior similar to such circuit. A carrier gas 7 may also be provided adjacent to the electrode 2. When the exemplary apparatus 100 is operated, an electrical arc or discharge 8 may be produced near a distal end of the electrode 2, and ionic particles 9 may be emitted from the electrode 2. Such particles can be expelled onto a nearby substrate and may adhere to such substrate, forming a strong mechanical bond. The an electrical arc or discharge 8 can be produced from the distal end of the electrode 2 using such exemplary one-sided electrode apparatus 100, even if the distal end of the electrode 2 is not proximate to an electrically grounded object. Thus, an electrical arc or discharge 8 may be produced in proximity to electrically nonconductive substrates, in contrast to conventional arc welding systems and the like. The distal end may be placed at an optimum distance in order to enhance the amount of bulk property change. For example if a large kinetic energy from the particle is required then the end may be placed in a fashion aligned with gravity to enhance the kinetic energy. This kinetic energy may be later transformed into a thermodynamic static potential. Energy interactions by particle chemical interactions and with the substrate or atmosphere are possible

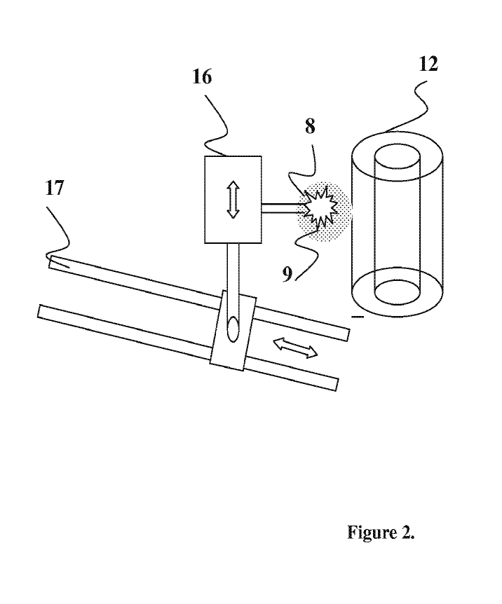

A further exemplary apparatus 200 is shown in FIG. 2 which can be used to provide a bulk modifying coating on a large substrate 12. Such exemplary apparatus 200 can include a deposition arrangement 16, which may be configured to produce an electrical arc or discharge 8 and emit ionic or other particles 9. The deposition arrangement 16 can be affixed to a translating arrangement 17, which can controllably move the deposition arrangement 16, e.g., along or over at least a portion of a large substrate 12. Thus, particles 9 can be deposited on a large substrate to form a coating thereon. The translating arrangement 17 can include or communicate with a controller (not shown) which can control the position and/or speed of the deposition arrangement 16 relative to the substrate 12. Thus, the location and amount of deposited coating formed by the particles 9 can be controlled. For example, such controller can control a position of the distal end of the electrode 8 relative to the substrate 12, e.g., provide a substantially constant distance between them, which can further allow a more uniform deposition of particles 9 on the substrate 12 as well as influence the bulk properties.

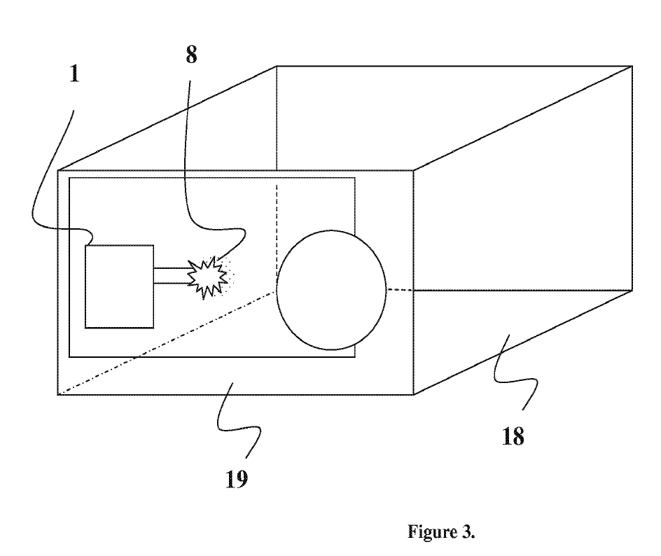

A still further exemplary apparatus 300 which can be used to provide a bulk modifying coating which is interactive with the bulk is shown in FIG. 3. Such exemplary apparatus 300 can include the deposition arrangement 16, which (as described above) may be configured to emit particles 9. The deposition arrangement 16 can be provided at least partially inside an enclosure (chamber) 19, and the enclosure 19 can further enclose an object 21 to be coated with a bulk modifying coating. Using this exemplary apparatus 300, the particles 9 can be deposited on an object 20 to form a coating thereon. Further, any of the particles 9 which are not deposited on the object 21 may coat the enclosure 19 or remain unattached in the enclosure. This exemplary configuration can assist in recovering such particle material, which may be then be reused or recycled. The belt 21 can be coated. Masking of specific objects can be carried out by standard masking techniques such that only selected area receive the bulk modifying coating

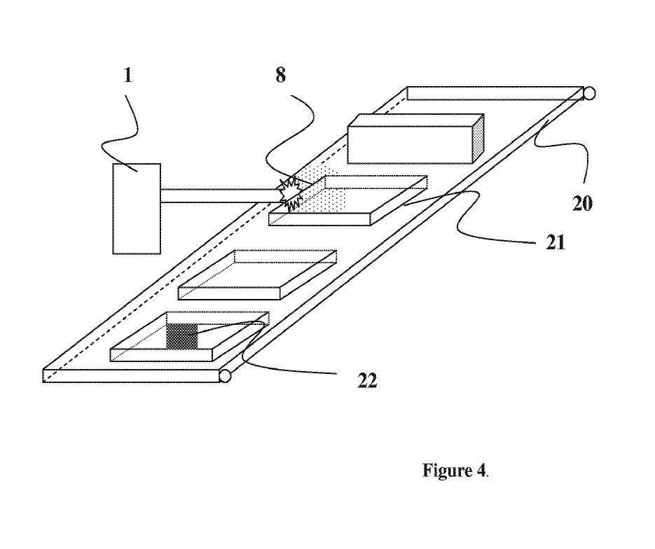

Yet another exemplary apparatus 400 which can be used to provide a coating is shown in FIG. 4. Such exemplary apparatus 400 can again include the deposition arrangement 16, which is configured to emit the particles 9. The deposition arrangement 16 can be provided in proximity to a conveyor belt 20 or similar transport apparatus. A plurality of objects 21 to be coated with a bulk modifying coating can be provided on the conveyor belt 20. Using this exemplary apparatus 400, particles 9 can be continuously deposited on a large number of objects 21 to form a coating thereon. A mask is shown 22 which can be used for selective coating. System parameters, such as speed of the conveyor belt 20 and intensity of discharged particles 9, area of the mask, may be adjusted to provide a suitable amount or thickness of the coating on the objects 21. Multiple passes with different mask locations is possible.

In further exemplary embodiments of the present invention, the electrode 2 can have a form of a wire that may be continuously fed as it is consumed to form particles. The wire may take the form of a coil which can be inserted or retracted from the inside of a long hollow tube 12. A control arrangement can be provided which includes, e.g., a feedback arrangement to control the speed at which such wire is fed, and which can preferably maintain a substantially constant distance between the distal end of such wire electrode 2 and the substrate being coated. Such control arrangement can be based, e.g., on mechanical, optical, electrical, or thermal sensors. The voltage provided by generator 1 and the diameter of the electrode 2 may also be controlled to provide desired particle sizes. For example, thinner electrodes and/or higher voltages may produce smaller particle sizes.

According to still further exemplary embodiments of the present invention, a plurality of electrodes 2 may be used, where different ones of the electrodes 2 may have different compositions and/or diameters to provide particular desired properties in the deposited coatings. Such electrodes 2 may be provided with electrical power to generate a discharge either simultaneously or sequentially as the distal ends of the electrodes 2 are moved over the substrate. Different electrical frequencies can be applied to the different electrodes 2, and distal ends of such electrodes may also be provided at different distances from the substrate being coated. Alternatively, a varying electrical frequency may be applied to a single electrode 2 to produce variations in particle sizes and/or other properties in deposited coatings. For example, coatings having a range of compositions, compositional gradients, and/or coatings with a plurality of layers can be created using a plurality of such electrodes 2.

In yet further exemplary embodiments of the present invention, a coating material may be provided on a substrate using a one or more single-sided electrode arrangement 100 similar to one shown in FIG. 1. The electrode 2 may have a form of a rod or wire, and can be electrically conductive or semi conductive or partially non conductive. A material or coating may be produced by providing an ionized discharge 8 (e.g., an electrical arc) at a distal end of the electrode 2, and placing a substrate to be coated in proximity to the discharge 8. The discharge 8 may be continuous, and it can be formed in the absence of a nearby object that is electrically grounded. The particles 9 produced by an interaction between the discharge 8 and the material of the electrode 2 can impinge on the nearby substrate and adhere thereto as well as influence bulk properties such as thermal conductivity. Vacancies and disclocations/disclinations may be generated or modified. Defects such as porosities, grain-boundaries, interface boundaries and cracks may change shape or blunt or be deflected or transported. It is recognized that all of these defects can have several variations such as a Schotky or Frenkel defect in an ionic material which is a variation of a vacancy but with charge issues.

The particles 9 which may be used to form the coating may have an average size that is less than about 1000 nm, less than about 800 nm, or preferably less than about 500 nm, or more preferably less than about 200 nm. As will be noted in the embodiments discussed below nano particles appear to be best suited for the invention. The particles 9 may have a shape that is approximately, spherical, cylindrical, acicular, or a mixture of these geometries. The small particles 9 which can form the coating can be unsintered or only partially sintered, and may retain an open porous structure even at high temperatures. The particles 9 can also remain adherent to the substrate and may resist further densification and pore closure even at high temperatures (e.g., about half of the absolute melting temperature of the substrate or a constituent thereof). The coating may further be resistant to wear or removal from the substrate under a range of conditions, e.g., rubbed or abraded against other objects, washed or otherwise cleaned, exposed to chemicals and solvents, etc. The particle and substrate may create conditions for bulk property changes. The surface area density of the surface coated with small particles may be approximately 2 to 10. The coating density could be a measure of the efficacy for bulk modification by the particles. In particular a lower density may offer high modification ability in some cases but not always. The particles or jointly with the substrate or film may have a glassy component. Composite particles and substrates are envisaged including glassy components, fibrous components and discreet or continuous components. In fact the use of angular glassy particles may be preferable or diamond particles with facets. It is thought that the interactive nature of the coating is important. Further it is thought that the interactive nature of the film, coating and surface of the substrate is also important in order to see substantial bulk modifications.

The grain boundary structure, dislocations or chemistry in the bulk region now modified by the coating especially under the bulk regions close to the substrate coating interface can be modified thus leading to a change in properties. For example high dislocation density boundaries may form replacing low angle boundaries or sessile dislocations may replace glissile dislocations. These terms are commonly understood in the materials literature. When nano particles especially less than 20 nm are employed for the coating it is likely that some may be trapped in defect sites including, pores and grain boundaries. It is also possible that there is a time and/or temperature dependence to the evolution of changed properties in the bulk i.e. the property development or changes may occur over a time period especially under a stress environment. Cold work that was trapped in the bulk because of the coating may recover or aid recrystallization whether static or dynamic. Again these are terms commonly known in the materials literature. The modification to the grain boundary may be through compositional reasons or stress (including stress cyclicity), defect creation or modification or recrystallization or grain growth.

The electrode 2 may be used to generate particles 9, which may then form at least a portion of the materials. For example, deposition of particles 9 may produce combinations and/or mixtures of the above-mentioned elements and/or compounds during deposition on a substrate. Such compounds and mixtures may include further compounds which can result from reactions of the particles 9 with, e.g., moisture, oxygen and/or nitrogen from surrounding air or deliberately introduced gases during deposition. For example, particles containing defect structure oxycarbonitrides could be formed and deposited on the substrate. Some of the substrates studied to provide examples of the invention are the three metallic alloys for boiler tube materials including two steels (T92 and S304H) and one nickel base super alloy (CCA617) that are listed in Table 1. The nominal chemical composition of these alloy tubes are given in Table 1. Other substrates examples by way of non metallic materials include polycarbonate, Polyethylene (HDPE and LDPE), Teflon, chlorine, carbon, fluorine and nitrogen polymers and biological materials, Polypropylene (PP), Polystyrene (PS), Polyvinyl Chloride (PVC), Polyethylene Terephthalate (PETO) and other common plastics used in for engineering articles. Porous materials including porous ceramics of alumina, silica, titanates, barium titanate, glass, diamond, silicon carbide, molysilicide and carbon, were also used as substrates or used as particles.

TABLE 1
Composition of boiler steels and Ni base alloy
by weight percent (nominal)

| Element, Wt % | T92 Ferritic Steel | S304H Steel | CCA617 Super alloy |
|---|---|---|---|
| C | 0.07 | 0.10 | 0.05 |
| Cr | 9.0 | 18.0 | 21.7 |
| Ni | — | 9.0 | 55.0 |
| Fe | Remainder | Remainder | 0.6 |
| Co | — | — | 11.25 |
| Mo | 0.5 | — | 8.6 |
| Al | — | — | 1.25 |
| W | 1.8 | — | — |
| Mn | 0.45 | 0.80 | 0.03 |
| Si | 0.03 | 0.20 | 0.10 |
| N | 0.06 | 0.10 | 0.01 |
| V | 0.2 | — | — |
| Nb | 0.05 | 0.40 | — |
| B | 0.004 | — | 0.002 |
| Cu | — | 3.0 | 0.01 |
| Ti | — | — | 0.4 |

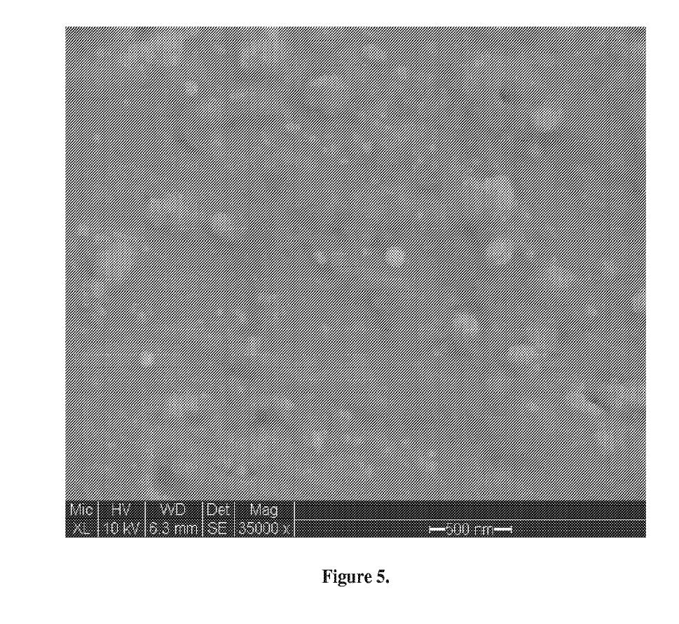

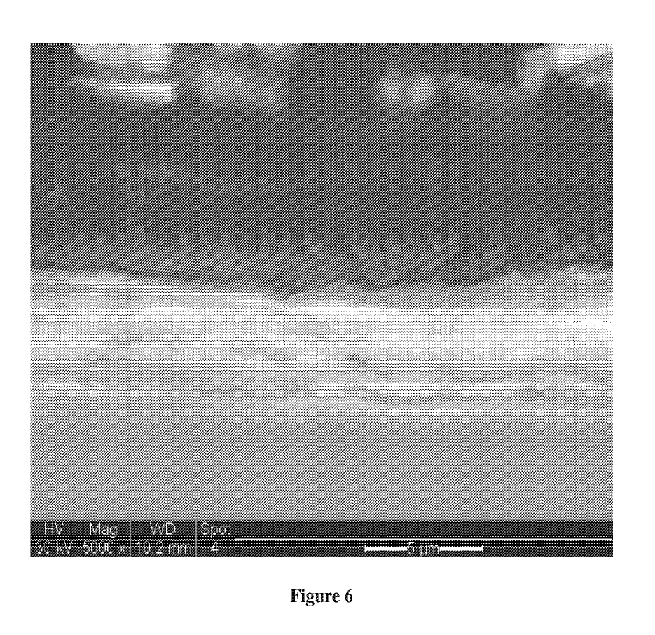

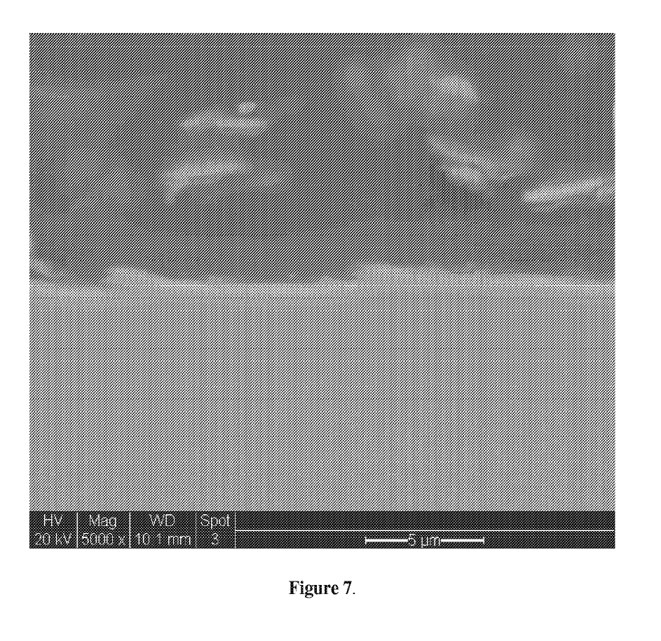

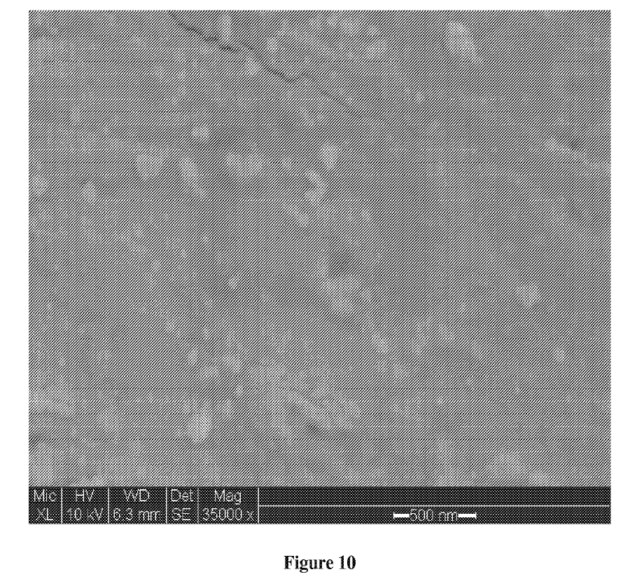

Magnified views of exemplary coatings deposited on substrates in accordance with exemplary embodiments of the present invention are shown in FIGS. 5-10. FIG. 5 shows a coating on a plastic. Bulk cracks may be sipped or deflected by the particles and influence the bulk properties as noted from micro structural features in FIG. 5 and FIG. 10. Another example, FIG. 6 shows a backscattered secondary electron image (“SEM”) image of a coating material containing silicon. The dark region on the very top is the mounting material. Under that is the coating with fine ˜50 nm particles, below that is what is thought to be a high cold work region in the bulk and far below that is a seemingly unmodified material. The coating was applied in this embodiment to a stainless steel surface alloy 304H. An exemplary SEM image of silica nanoscale particles which were deposited on a CCA617 substrate in accordance with exemplary embodiments of the present invention is shown in FIG. 7. In this case the coating is less than 300 nm thick.

FIG. 7 is an exemplary scanning electron microscope (“SEM”) image of small particles containing silicon (thought to be glassy) which were deposited on a stainless steel substrate. Such particles have been observed to be strongly adherent to the substrate, and did not rub off even when applying mechanical shear. The mounting (Bakelite) is the black part above the tin coating. Note in particular the bulk modification which extends to over a micron i.e. about 500% more than the coating thickness.

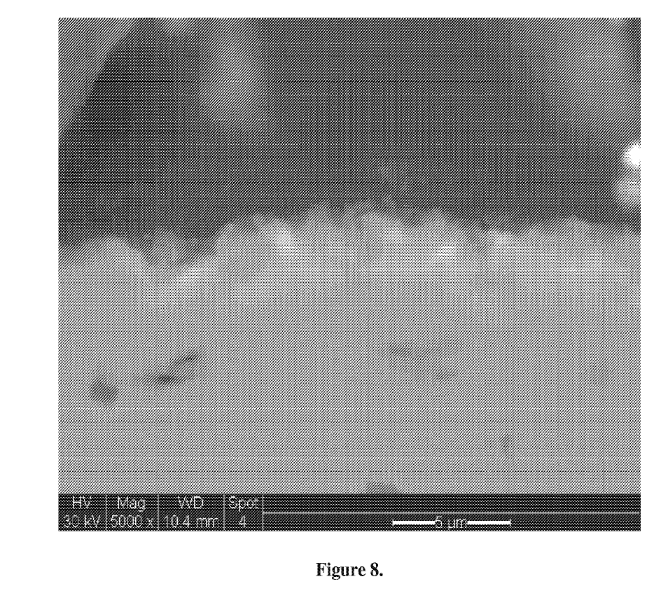

FIG. 8 is an exemplary SEM image of particles which were deposited on a T92 alloy. Note again that the bulk microstructure is influenced. Such particles have been observed to be strongly adherent to the substrate, and did not rub off even when applying mechanical shear. The mounting (Bakelite) is the black part above the tin coating. Note in particular the bulk modification extended to over a micron i.e. about 500% more than the coating thickness.

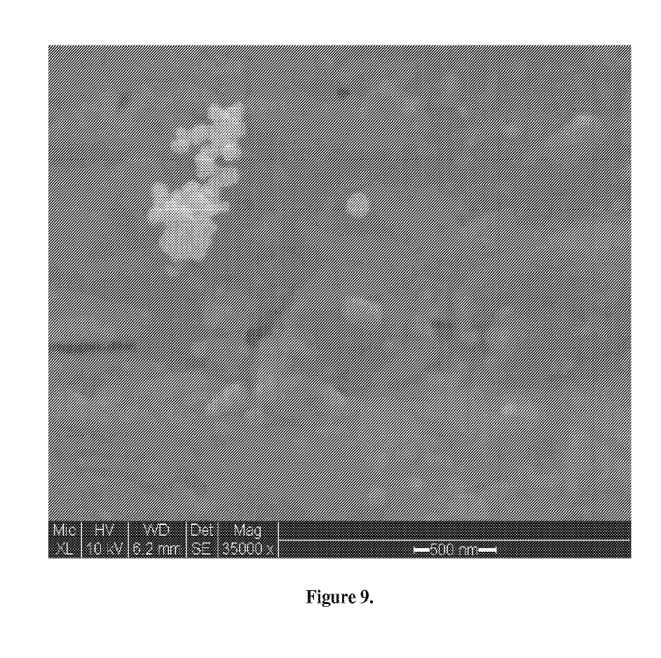

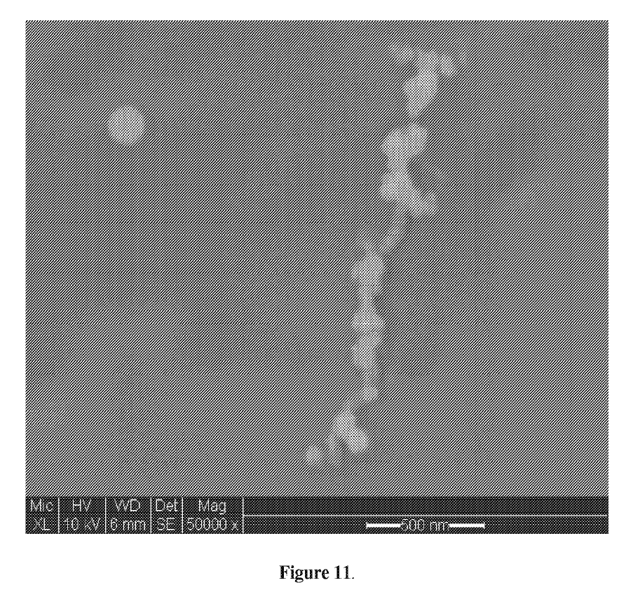

Coatings may be made on metals, ceramics, polymers, composites etc. for beneficial property enhancements. FIG. 5 and FIG. 10 in particular shows crack travel modification in the bulk by the particles. FIG. 9 is an exemplary SEM image of particles on and in the substrate after a very heavy dose of coating. FIG. 10 is an exemplary SEM image of particles on and in the substrate after a light dose of coating. FIG. 11 is an exemplary image showing regions of a coating where particles which are either connected in a region or are individually attached to the substrate.

The small particles, which may be microscopic or nanoscale (e.g., having an average size that is less than about one micron), can be deposited as one or more layers on a substrate. Preferably, such deposited particles will not be in a substantially sintered condition, e.g., they may still exhibit a degree of porosity after being deposited on a substrate. A cross sectional view of such a porous coating was shown in FIG. 8. For some of substrates which are porous or soft, like polymeric materials (plastics) the delineation between the coating and original substrate is not like shown above but extends further into the substrate surface i.e. into the bulk and thus modifies the bulk also by particle incorporation.

Exemplary durable materials in accordance with exemplary embodiments of the present invention can be created using the exemplary apparatus shown in FIG. 1. For example, a commercial generator 1 may be used which provides alternating current at approximately 14 MHz from a 120 volt, single phase input. Such generator can be provided in electrical contact with one side of a conventional Pi circuit (e.g., inductive coil 3 and capacitors 4, 5, 6). For example, the coil 3 may have a diameter of several inches (e.g., between about 2 inches and 6 inches), and the capacitors 4, 5, 6 can have a capacitance value of between about 30 picofarads and about 100 picofarads. The Pi circuit may include such components (e.g., coil 3 and capacitors 4, 5, 6) which may have values that lie outside these approximate ranges. The other side of the Pi circuit can be provided in electrical contact with one or more electrodes 2. Such electrodes 2 can be, e.g., wires which contain one or more particular compositions that can be used to form the exemplary coatings described herein.

When the generator 1 is powered, the distal end of the electrode 2 may be provided a few inches away from the substrate to be coated. For example, a distance of a between about 1 inch and about 6 inches can be used, or preferably a distance of about 3-4 inches. Other distances may be used depending on the amount of power supplied, the diameter and material of the electrode, etc. The distal end of the electrode can be passed over a portion of the substrate to cover a particular area thereof with the exemplary bulk modifying coating. A substrate exposure time of several seconds (e.g., about 1-10 seconds) may be sufficient to form such exemplary coating on the substrate. The exposure time can represent, e.g., a duration of time in which power is provided to emit particles from an electrode that is stationary relative to a substrate, or a duration of time in which particles from an electrode are provided onto a particular portion of a substrate, where the electrode and substrate are in relative motion to each other. Such residence time can be increased, e.g., by providing multiple passes of an electrode over a particular portion of a substrate. Such multiple passes using at least two different electrodes on different passes (or using one electrode supplied with electrical energy having different characteristics such as, e.g., frequency for different passes) may be used to create multilayered coatings which can include a plurality of layers having different compositions, particle sizes, or other properties.

The particles formed from the electrode, which may be deposited on the substrate to form an coating, may preferably have a size on the order of a few hundred nanometers or less. For example, the average particle size may be less than about 1000 nm, less than about 800 nm, preferably less than about 500 nm, or more preferably less than about 200 nm. Smaller electrode diameters may be used to form smaller particles. For example, an electrode having a diameter of about 1 mm or less can be used to form particles having a size of a few hundred nm or less. Several such thin electrodes may be provided in proximity to each other to cover a larger area of a substrate more quickly and/or uniformly.

The coating formed on the substrate can be very thin, e.g., on the order of several particle layers or less (see e.g. FIG. 7). Thick or thin coatings may be preferable depending on the application and cost, i.e. with respect to cost, durability, formation time, etc. For example, exemplary coatings can have a thickness that is less than about 2000 nm, or preferably less than about 1000 nm in certain boiler or capacitor applications. In certain exemplary embodiments of the present invention, the coating thickness can be less than about 800 nm, or less than about 500 nm, or even less than about 250 nm. The exemplary particle and coating dimensions described herein can provide coatings which may be very durable and firmly adherent to the substrate or to each other. It is by now well known that very small nano particles may exhibit unusual properties. However the present invention deals with coatings that influence bulk properties. Several of the precise relationships between the nanomaterial and coating thickness which impact the bulk properties are relatively unknown to us at this time however we anticipate that unusual affects of nanocoatings especially comprising nano particles under 50 nm or more preferably 20 nm. We anticipate that benefits of the particle to the bulk may not always manifest completely only during the initial coating application but could be mainly manifested subsequently as can be noted in some of the examples below which discuss bulk microstructure modifications, (which are a way of inferring changes in the bulk property differences), when observed without the coatings and compared with the presence of the adherent coating during a similar air or steam oxidation exposure.

All previously identified electrodes materials and shapes that may be used in accordance with PCT/US2006/060621 and PCT/US2007/085564 and U.S. patent application Ser. No. 11/098,474 are fully incorporated by reference. Exemplary coatings which include nonconductive materials may be formed in several ways. For example, a nonconductive thin rod or fiber may be covered with a conductive material to provide such electrode or vice-a-versa. In one exemplary embodiment, a silica fiber provided with a metallic coating (e.g., silver, tungsten, or iron) may be used as an exemplary electrode. Alternatively, one or more nonconductive rods or fibers may be provided adjacent to one or more conductive rods or fibers. A discharge formed at the distal end of a conductive rod or fiber as described herein can produce particles of both the conductive and nonconductive materials, which may then be deposited together on a substrate to form a coating in accordance with certain exemplary embodiments of the present invention. Electrical conductivity of such materials may change when deposited. For example, conductive oxide electrodes may gain oxygen during deposition and become nonconducting after being deposited. In certain exemplary embodiments of the present invention, a plurality of layers may be sequentially deposited using electrodes having different compositions, where certain layers may be conductive and others may be nonconductive. In this manner, materials exhibiting a variety of dielectric properties can be provided.

Two or more layers of particles may also be deposited on a substrate to form a coating containing particles of more than one composition. For example, a first deposition may be applied to a substrate using a first electrode having a first composition, and a second deposition may then be applied to the substrate using a second electrode having a second composition. Between the several depositions the new substrate surface and new bulk properties could be modified further by heat treatment or chemical reaction including cleaning. This procedure can be further repeated if desired to improve not only surface properties but also bulk. Bulk property enhancement is considered to be anywhere in the non coating part of the structure. In this exemplary manner, a coating containing particles having different compositions may thus be provided for enhancing different bulk properties. Exemplary coatings may not have the same composition as the initial starting material of the electrode(s) used to form them. For example, non-stoichiometric particles and other compounds may be produced during formation of such exemplary coatings by reaction of the starting materials with each other and/or with ambient substances such as, e.g., oxygen, nitrogen, carbon-containing gases, or moisture.

A combination of metallic and oxide particles may further be used as a coating such as, e.g., a coating containing Si, Al, Mo and SiO2. An oxide which forms in such exemplary coatings may be dispersed as separate particles within the coating or the coating and substrate structure. Alternatively, a surface of certain particles may oxidize while the interior of such particles may remain metallic. The oxide formed can be porous or non porous. Such oxides may be intentionally formed or enhanced, e.g., by exposing metal-containing coatings to an oxidizing atmosphere after they are deposited, optionally with simultaneous heating of the coatings. Such oxidation may also occur spontaneously in such coatings, e.g., during application or use. Alternatively, deposited coatings may be subjected to a reducing treatment after they are deposited on a substrate. The bulk may thus be influence in manner to change its properties by interaction between the substrate surface, the coating and the environment.

Exemplary embodiments of the present invention may be used to coat various objects with coatings in situ. For example, the exemplary apparatus described herein and shown, e.g., in FIG. 1, may not require any electrical grounding of the substrate. Thus, exemplary structures may be applied to a variety of objects, including nonconductive objects, without relocation or removal of the object. For example, common objects such as boilers components, common plastics, may be coated simply by providing an electrode having a discharge as described herein in proximity to the object. If the bulk properties of a coated object somehow diminish over time, they can be ‘rejuvenated’ by reapplying a coating of the material as described herein. Cracks that develop in boiler or heat exchanger materials during use may be healed while simultaneously improving the bulk properties. In some applications the coating could dramatically influence the overall oxidation of the materials for example in hot air or air and steam and/or more generally when reacted with an environment or object with a film or by itself. In such instances the benefit of the particle to the bulk may not manifest completely fully during the initial coating but could be noted with time as may be noted in some of the examples shown below which discuss bulk microstructure modification differences when observed without coatings and when observed with coating during a similar air or steam oxidation exposure. Hole creation or creation of passages in the bulk is enabled by the invention. One such example can be noted in FIG. 9.

In several of the examples discussed below the change in properties whether instantaneous or over time may be more than two times if the particles were not present.

### Examples

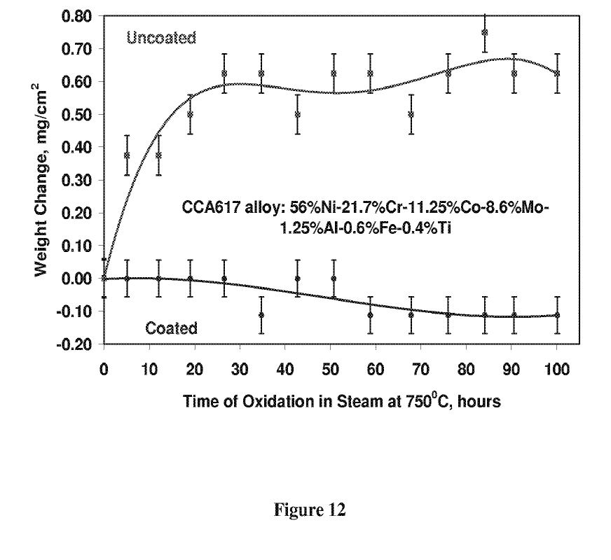

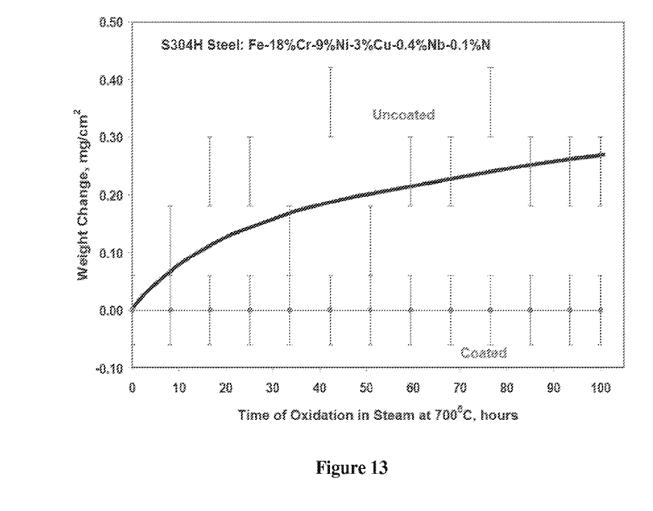

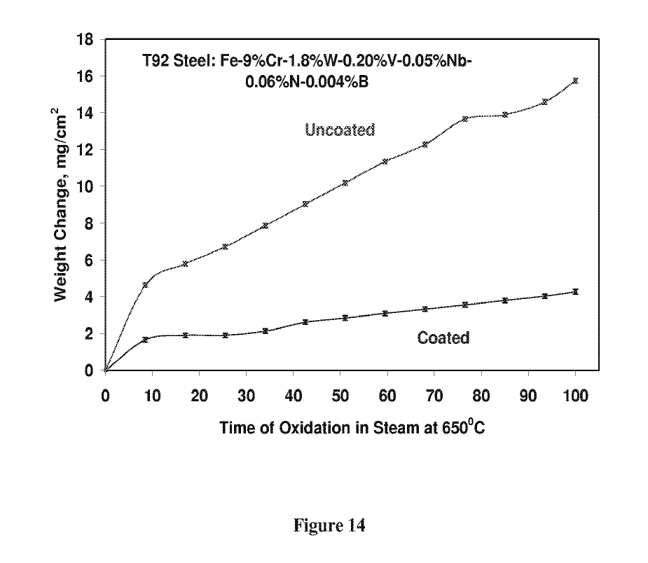

Weight change measured during the steam oxidation up to 100 hours is shown in FIGS. 12, 13, and 14 for the CCA617, S304H, and T92 steel, respectively with and without a particulate coating of this invention (see FIGS. 5-10). Note that for all the alloys the nanostructured coated coupons did not show any significant weight change (similar results were obtained for air oxidation). The error bars indicate the possible experimental error or measurement error reflecting the maximum sensitivity of the weighing machine. Differences in oxide thicknesses or films reflect differences in at least one constituent from the substrate and this influence also the bulk properties in such a manner.

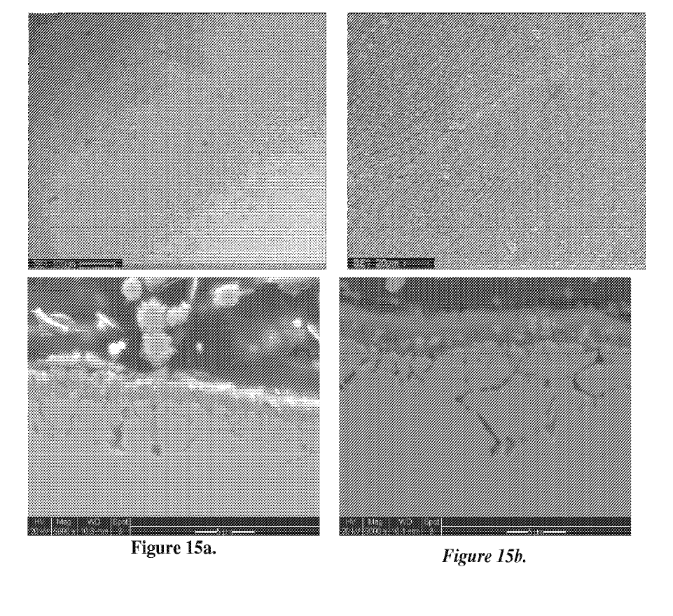

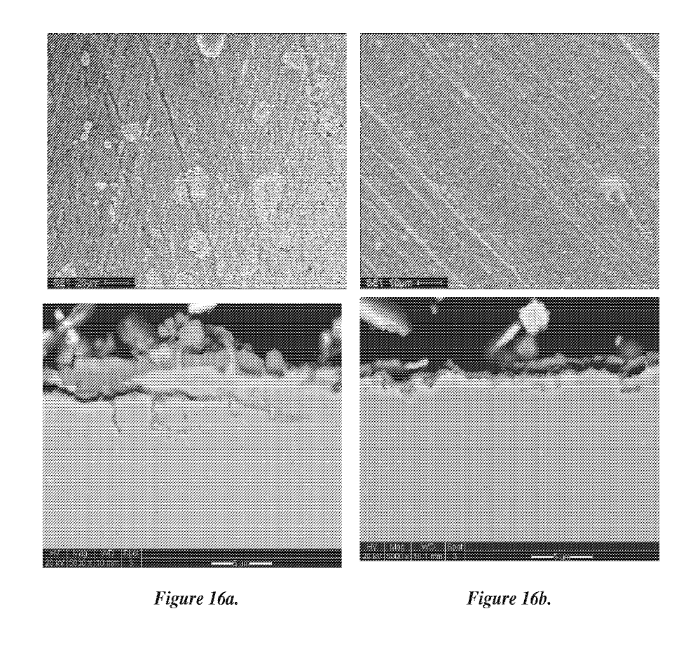

SEM/EDS confirmed the presence of Mo, Si, Al and O in the coating. SEM micrographs of the surfaces and polished cross-sections of the uncoated and coated coupons of CCA617, Super304H and T92 steel that were subjected to steam oxidation for 100 hours are shown in FIGS. 15, 16 and 17 respectively. An oxide scale was observed in all cases. The very black part on top of the cross-section micrographs is the mount (Bakelite). Thus the structure initially applied can include for example a bulk-encompassing film of silicon oxides or alumina or chromia (i.e. binary or higher order of oxides of aluminum or chromium or combinations) which are all understood to form either during the coating process or during further exposure to temperature in air or other environments. These films which may or may not include the oxides can be crystalline or glassy or combined but are seen to be different in some manner, including size. As the films are a part of the bulk either from the initial state or during further exposure they are considered to finally become bulk regions which are modified by the coating. Note again that the bulk region is thicker than the coating plus the immediate substrate surface. SE is the secondary electron image and BSE is the Back scattered electron image.

The coated CCA 617 sample revealed a thinner oxide scale (˜1 μm) compared with the counterpart uncoated sample (FIG. 12). Analysis of the peaks in XRD spectra recorded from the oxidized surface indicated the presence of Cr₂O₃, together with the FCC matrix underneath in both samples. Analysis of EDS spectra recorded from the surface and cross-section confirmed the presence of the Cr₂O₃ oxide scale. Modest levels of Si were also present in the oxide scale in the nano coated sample. In addition, the presence of thin films of an Al-rich oxide (dark in contrast) was noted along the grain boundaries in the cross-section samples. Some of the oxides were present to a greater extent and deeper into the substrate in the uncoated coupons. Again the particulate coatings are thus thought to have modified the bulk structure differently when compared to an uncoated object given the same thermal or environmental treatment of the substrate but without the coating

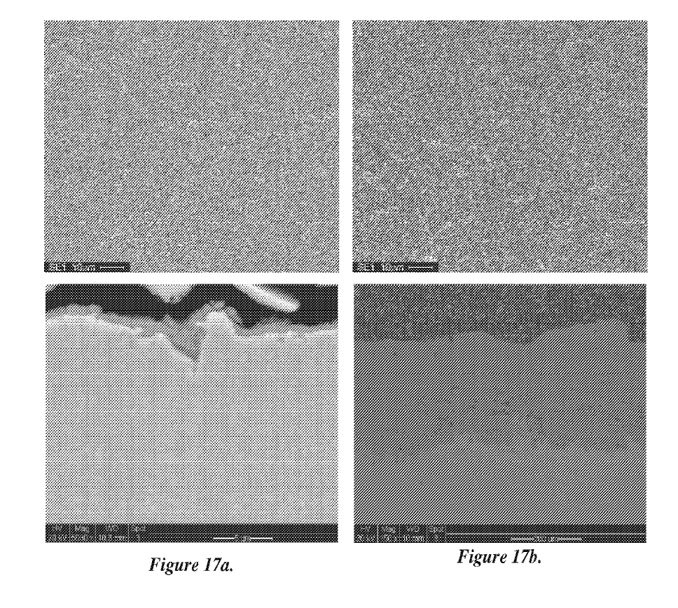

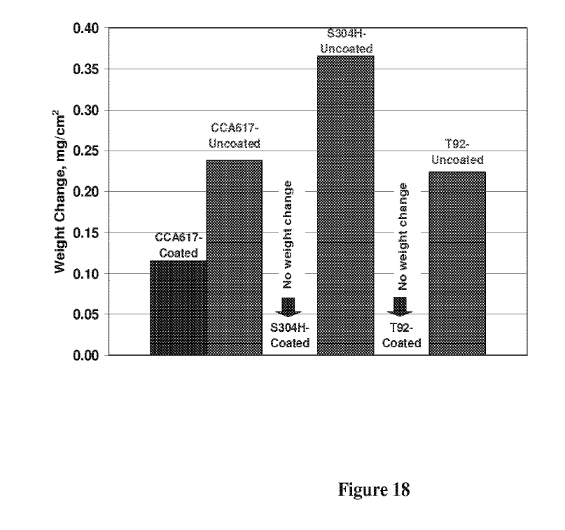

The difference was also observed for a stainless steel substrate. The oxide scale on the coated Super304H sample was thinner in the nanoparticle coated samples compared with the counterpart uncoated sample (FIG. 15). XRD analysis of the oxidized surface revealed the presence of Cr₂O₃, (Fe, Mn, Cr)O₄ and the fcc matrix in both samples, which was also confirmed by EDS in the SEM. Often XRD analysis is unable to pick up the subtle but important differences, the microstructures and thicknesses were different as is noted. A combination of several analytical techniques may be required to identify the differences. Films are identified in the micrographs and may or may not correspond to the oxide. SEM micrographs of steam oxidized T92 steel both coated and uncoated are shown in FIGS. 17a and 17b, respectively. The nano-coated steel has a fine scale oxide distribution (FIG. 17a) compared with the coarse oxides noted (FIG. 17b) in the uncoated steel. The cross-section samples also reveal that the oxide scale in the nano-coated sample is substantially thinner (1-2 μm) than that in the uncoated sample (˜100 μm). One set of coated and uncoated tube coupons were subjected to the Static Air Oxidation for 500 hours. Another set of tube coupons was oxidized for 1000 hours. The word static is used to represent that these coupons were stationery for the full 500 or 1000 hours inside the furnace at the oxidizing temperature. The weight change after 500 hours of oxidation in the box furnace for the coated and uncoated tube coupons of the CCA 617, S304H, and T92 steel are given in the Table 2, and a corresponding bar chart is shown in FIG. 18.

TABLE 2
Summary results of 500 hour Static Air Oxidation

| | | Temperature | Time of | |
|---|---|---|---|---|
| | Coated or | of Oxidation, | Oxidation, | Weight change, |
| Alloy | Uncoated | ° C. | Hours | mg/cm² |
| CCA617 | Coated | 700 | 500 | 0.1102 |
| | Uncoated | 700 | 500 | 0.2357 |
| S304H | Coated | 700 | 500 | 0.0000 |
| | Uncoated | 700 | 500 | 0.2461 |
| T92 | Coated | 650 | 500 | 0.0000 |
| | Uncoated | 650 | 500 | 0.2412 |

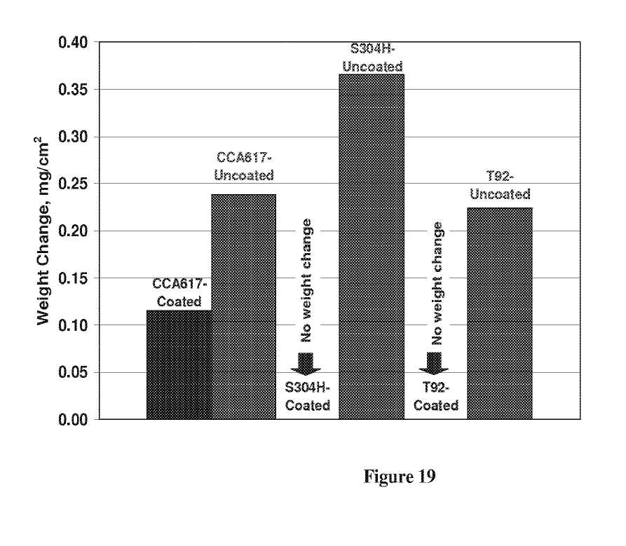

One set of coated and uncoated tube coupons of the CCA617, S304H, and T92 steel were subjected to static air oxidation in a box furnace for 1000 hours in a single cycle. The weight change data is given in Table 3, and the corresponding bar chart is shown in FIG. 19.

TABLE 3
Summary 1000 hour Static Air Oxidation

| | | Temperature | Time of | |
|---|---|---|---|---|
| | Coated or | of Oxidation, | Oxidation, | Weight change, |
| Alloy | Uncoated | ° C. | Hours | mg/cm² |
| CCA617 | Coated | 700 | 1000 | 0.1159 |
| | Uncoated | 700 | 1000 | 0.2379 |
| S304H | Coated | 700 | 1000 | 0.0000 |
| | Uncoated | 700 | 1000 | 0.3656 |
| T92 | Coated | 650 | 1000 | 0.0000 |
| | Uncoated | 650 | 1000 | 0.2235 |

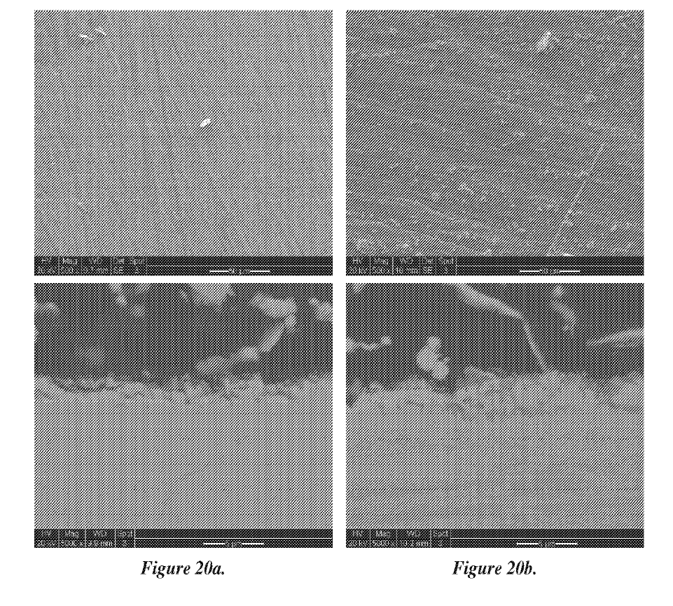

SEM micrographs of the coated and uncoated samples of the CCA617, Super304H and T92 steel oxidized for 500 hours and 1000 hours are shown in FIGS. 20 through 23.

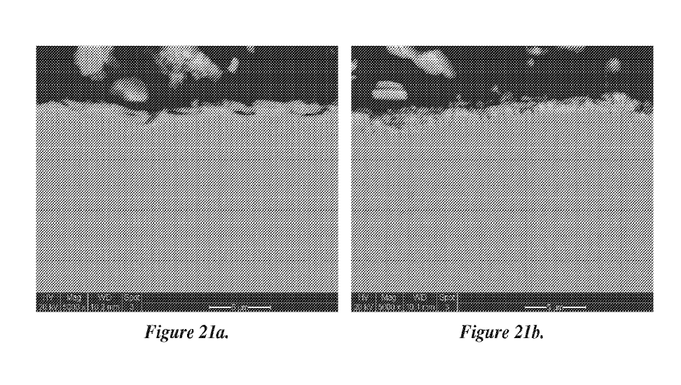

The coated CCA 617 sample revealed a thinner oxide scale (˜0.5-1 μn) compared with the counterpart uncoated (3-5 μm) sample (FIGS. 20 and 21). An analysis of the peaks in XRD spectra recorded from the oxidized surface indicated the presence of Cr₂O₃, together with the FCC matrix underneath in both samples. Analysis of EDS spectra recorded from the surface and cross-section confirmed the presence of the Cr₂O₃ oxide scale. Modest levels of Si were also present in the oxide scale in the nanoparticle coated coupon. In addition, the presence of particles of an Al-rich oxide (dark in contrast) was noted along the grain boundaries in the cross-section samples (FIGS. 20, 21). These oxides were present to a greater extent and deeper into the substrate in the uncoated coupons (FIGS. 19b and 20b). Longer time exposure to 1000 hours did not cause much thickening of the oxide scale in the nanoparticle-coated sample compared with the counterpart uncoated sample (FIG. 20). This experiment is another embodiment which shows that the bulk structure is influenced differently between coated and uncoated materials because of the presence of the coating and substrate.

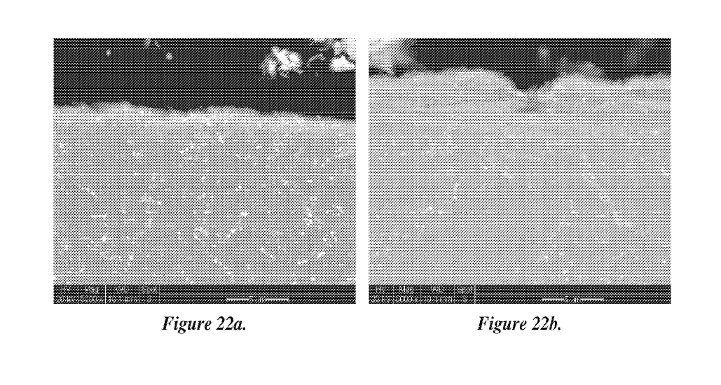

SEM micrographs of the coated and uncoated T92 alloy samples oxidized in air at 650° C. for 1000 hours are shown in FIG. 22 (a) and (b). The oxide layer was quite thin in the nanoparticle-coated sample but also thinner than that in the uncoated sample. In this embodiment the particulate coating is also enabled by the oxidation process following a first application of a particulate coating. Note again clearly the bulk differences for the depth of the micrograph between FIG. 22(a) and (b).

In the case of a special stainless steel, Super304H the film was thinner in the nano particle coated material compared to uncoated. XRD analysis of the oxidized surface revealed the presence of Cr₂O₃, (Fe, Mn, Cr)O₄.

An indication of the long duration of bulk property differences between objects with the invention and objects without the invention was noted even after 3000 hr tests. In one embodiment it was noted that nanoparticles (of average particle size less than 150 nm) comprising a coating of nanothickness (less than 1000 nm) for a object made of a Fe—Cr—Al alloy, displayed enhanced erosion resistance even after 3000 hrs of use in a combustion-gas flow environment when compared to an uncoated article. The erosion resistance was unanticipated because the nano coating would have been expected to possibly loose its efficacy much sooner if only the surface wear of the coating or only substrate surface is considered. However, it appears that because regions of the bulk were strengthened against erosion from the combustion particulate matter and reactive hot gases, even after thousands of hours of harsh testing. Although erosion is a surface deterioration phenomena, we associate the long time benefits of erosion to be reflective of the change in bulk properties at least in some regions of the substrate interior to the initial surface on which the particulate coating was applied. A surface is a two dimensional entity and bulk refers to a three dimensional entity even when the third dimension is small e.g. greater than the thickness of the coating preferably greater than two times the thickness of the coating.

In further exemplary embodiments of the present invention, rough or defective surfaces or objects may be treated by filling cracks, crevices and/or pores with materials using the exemplary method and apparatus described herein. Alternatively, modified materials may be provided using the exemplary apparatus, method, and compositions described herein in order to obtain beneficial results.

Having thus described in detail preferred embodiments of the present invention, it is to be understood that the invention defined by the appended claims is not to be limited to particular details set forth in the above description, as many apparent variations thereof are possible which lie within the scope of the present invention as recited in the appended claims. Certain modifications and variations of the method, apparatus, and compositions described herein will be obvious to those skilled in the art, and are intended to be encompassed by the following claims.

When referring to the claims below it is obvious that the chemical nature or size of the coating particles, or the coating process are all encompassed by a reference to a bulk modifying coating. This is in-line with the commonly held knowledge where a process and composition both influence the microstructure and hence properties of a material.

1. A structure comprising:
a substrate; and
a coating applied to a surface of the substrate;
wherein the coating comprises a plurality of particles, wherein each of the particles at least partially adheres to the substrate or another one of the particles, wherein at least one portion of the substrate is covered by the coating, and wherein the at least one portion of bulk properties are modified by the coating.

2. The structure according to claim 1 further comprising
a bulk modifying coating applied to a surface of the substrate
wherein the coating comprises a plurality of coating particles, wherein each of the coating particles at least partially adheres to at least one of the substrate or another one of the substrate particles, wherein at least one portion of the substrate is covered by the coating, and wherein at least one portion of the substrate is modified by the coating and wherein the substrate is modified having said substrate particles.

3. The structure according to claim 2
wherein at least one portion of the bulk is modified, during or after the coating application.

4. The structure according to claim 2 further comprising:
a film;
wherein the film is at least partially adhered to each of the coating particles of the coating.

5. The structure according to claim 1, wherein the coating is substantially inorganic and wherein at least one of the particles comprising the coating in comprised of a material that is glassy or composite.

6. (canceled)

7. (canceled)

8. The structure according to claim 1, wherein at least a part of the structure bulk comprises a region selected from the list consisting of a cold worked region, a recovered region and a region with grain boundaries wherein at least a part of the grain boundary is modified by the coating.

9. (canceled)

10. (canceled)

11. The structure according to claim 1, wherein the composition of a part of the bulk region is modified by at least one component of the coating material.

12. The structure according to claim 1, wherein at least a part of the grain boundary of a part of the bulk is modified by the coating.

13. The structure according to claim 1, wherein the bulk additionally comprises a adherent protective film on the substrate or a polaron or a thermodynamic potential.

14. The structure according to claim 1, wherein the bulk contains sessile dislocations or dislocation loops.

15. The structure according to claim 1, wherein the coating comprises at least one of silicon carbide, siliconoxycarbide, siliconoxynitrocarbide, ironsilicate, molybdenumcarbosilicide, or a further carbide.

16. (canceled)

17. The structure according to claim 1, wherein the coating comprises a grain or interface boundary.

18. The structure according to claim 1, wherein the bulk modification includes a charge separation.

19. The structure according to claim 1, wherein the structure comprises a sulfide, nickelide, aluminide, oxide, nitride, oxycycarbide, oxynitrocarbide and combinations thereof.

20. (canceled)

21. (canceled)

22. The structure according to claim 1, wherein the coating comprises a first layer and a second layer, wherein the first layer has a first composition and the second layer has a second composition, and wherein the second composition is different from the first composition.

23. The structure according to claim 1, wherein the particles have an average size of less than 20 nm to 1000 nm.

24. (canceled)

25. (canceled)

26. (canceled)

27. (canceled)

28. (canceled)

29. (canceled)

30. (canceled)

31. The structure according to claim 1, wherein the coating has a thickness of less than 250 nm to 2000 nm.

32. (canceled)

33. (canceled)

34. (canceled)

35. (canceled)

37. The structure according to claim 1, wherein the coating comprises a first layer and a second layer, wherein the first layer has a first average particle size and the second layer has a second average particle size, and wherein the second average particle size is different from the first average particle size.

38. The structure according to claim 1, wherein the structure has a form selected from the group consisting of a biological implant a medical instrument, a household utensil, a transportation vehicle, a lever, a knob, a key, a switch and a button.

39. (canceled)

40. (canceled)

41. (canceled)

42. (canceled)

43. (canceled)

44. An apparatus for providing a durable coating on a substrate, comprising:
at least one electrode; and
an electrode arrangement which is configured to produce an electrical arc at a distal end of the electrode without the distal end of the electrode being in proximity to an electrically grounded object, and which is further configured to provide particles discharged from the arc onto the substrate to form the bulk modifying coating, wherein a modified bulk thickness is at least two time the thickness of the coating.

45. (canceled)
